(19) United States
(12) Patent Application Publication
(10) Pub. No.: US 2026/0038554 A1
(43) Pub. Date: Feb. 5, 2026

(54) NON-VOLATILE GAIN MEMORY CELL

(71) Applicant: Micron Technology, Inc., Boise, ID (US)

(72) Inventors: Kamal Karda, Boise, ID (US); Durai Vishak Nirmal Ramaswamy, Boise, ID (US)

(21) Appl. No.: 19/279,942

(22) Filed: Jul. 24, 2025

Related U.S. Application Data
(60) Provisional application No. 63/677,342, filed on Jul. 30, 2024.

(51) Int. Cl. G11C 11/22; H10B 53/30

(52) U.S. Cl. CPC G11C 11/221; G11C 11/2273; G11C 11/2275; H10B 53/30

(57) ABSTRACT

Methods, systems, and devices for a non-volatile gain memory cell are described. The memory cell may include a first transistor coupled with a digit line and comprising a gate terminal coupled with a word line, a ferroelectric material coupled with the first transistor and a plate line, a second transistor coupled with the plate line, and a third transistor coupled with the second transistor and the digit line. The second transistor including a gate terminal coupled with a node between the ferroelectric material and the first transistor. The third transistor including a gate terminal coupled with the word line.

### CROSS REFERENCE

The present Application for Patent claims priority to Provisional U.S. Patent Application No. 63/677,342 by Karda et al., entitled “A NON-VOLATILE GAIN MEMORY CELL,” filed Jul. 30, 2024, which is assigned to the assignee hereof, and which is expressly incorporated by reference in its entirety herein.

### TECHNICAL FIELD

The following relates to one or more systems for memory, including a system with non-volatile gain memory cells.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports a non-volatile gain memory cell in accordance with examples as disclosed herein.

FIG. 2 shows an example of a non-volatile gain memory cell in accordance with examples as disclosed herein.

FIG. 3 shows an example of a process flow that supports operation of a non-

volatile gain memory cell in accordance with examples as disclosed herein.

FIG. 4 shows an example of a non-volatile gain memory cell in accordance with

examples as disclosed herein.

FIG. 5 shows an example of a process flow that supports operation of a non-volatile gain memory cell in accordance with examples as disclosed herein.

FIG. 6 shows a block diagram of a memory system that supports a non-volatile gain memory cell in accordance with examples as disclosed herein.

FIGS. 7 and 8 show flowcharts illustrating a method or methods that support a non-volatile gain memory cell in accordance with examples as disclosed herein.

### DETAILED DESCRIPTION

In some memory systems, a memory cell may comprise a transistor coupled with a floating gate (e.g., a metal block) and a logic state may be written to the memory cell by charging the floating gate to a voltage level corresponding that logic state. But the transistor may have a non-trivial leakage current that reduces the retention time of the memory cell (e.g., the duration of time the logic state can be maintained without performing a refresh operation). For example, the transistor may have a leakage current that is much greater than the intrinsic capacitance of the floating gate, which may cause the voltage level of the floating gate to decrease (e.g., dissipate through the transistor) over time.

According to the techniques and designs described herein, a ferroelectric material may be added to a memory cell so that a stored logic state is represented by the capacitance of the ferroelectric material instead of the voltage level on the floating gate. Such a design may render the memory cell resistant to the leakage current of the transistor so that the memory cell is effectively non-volatile, which may allow the memory system to perform refresh operations less frequently or omit refresh operations and/or refresh circuitry entirely. Among other advantages, such a design may also enable non-destructive reads of the memory cell (e.g., read operations that do not destroy the logic state stored at the memory cell), which may allow the memory system to perform write-back operations less frequently or omit write-back operations and/or write-back circuitry entirely. Additionally, such a design may enable intrinsic amplification at the memory cell (e.g., the memory cell may be a gain memory cell), which may allow the memory system to reduce and/or omit amplification components in sensing circuitry.

In addition to applicability in memory systems as described herein, techniques for a non-volatile gain memory cell may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving memory reliability and retention, among other benefits.

In addition to applicability in memory systems as described herein, techniques for a non-volatile gain memory cell may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by reducing materials used in production of electronic devices (e.g., if refresh circuitry or amplification components are simplified, reduced, or omitted), which may reduce electronic waste, among other benefits.

Features of the disclosure are illustrated and described in the context of systems and architectures. Features of the disclosure are further illustrated and described in the context of memory cells, process flows, and flowcharts.

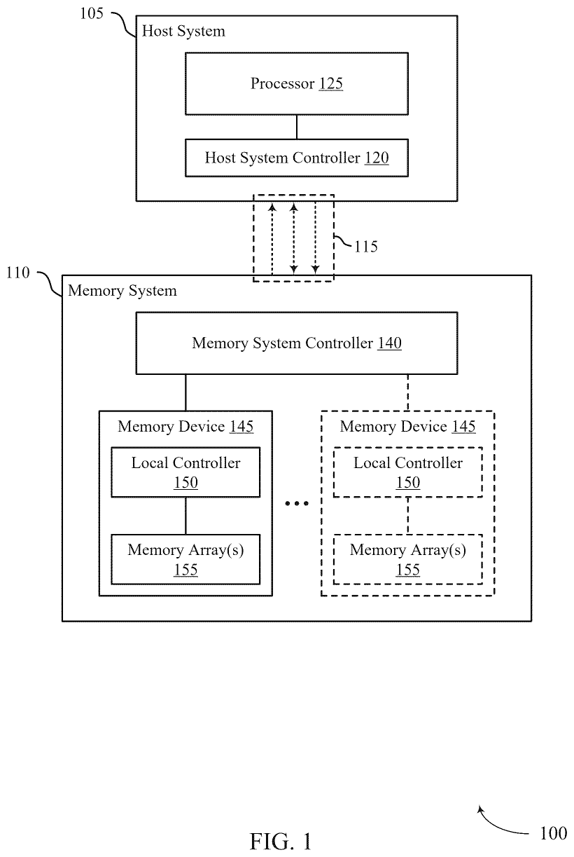

FIG. 1 illustrates an example of a system 100 that supports a non-volatile gain memory cell in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). A memory array 155 may include memory cells of the type described herein, which may be referred to as non-volatile gain memory cells.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

A memory array 155 may include various arrangements of access lines, such as word lines, digit lines, and plate lines. An access line may be a conductive line that is coupled with a memory cell, and may be used to perform access operations (e.g., read operations, write operations) on the memory cell. Memory cells may be positioned at intersections of access lines, and an intersection may be referred to as an address of a memory cell. The logic state stored by a memory cell may be outputted by the memory cell as a signal (e.g., a current, a voltage) and may be sensed by a sense component. For example, the sense component may compare the signal with a reference signal to determine whether the signal is representative of a logic 0 or a logic 1. If the difference between signals representative of different logic states is small, the sense component may include an amplifier that amplifies the difference (e.g., before comparison with the reference signal) to improve the reliability (e.g., accuracy) of the sense operation.

In some examples, the memory cells in a memory array 155 may be configured to store logic states by charging floating gates of the memory cells to voltage levels representative of the logic states. To read a memory cell, the memory cell may be operated (e.g., by biasing various one or more access lines) so that a signal whose amplitude is based on (e.g., a function of) the voltage level stored on the floating gate is outputted through a transistor (e.g., an n-type transistor) onto the digit line coupled with that memory cell. But due to the leakage current of the transistor, the voltage level of the floating gate may have dissipated through the transistor in between writing and reading, which may result in an inaccurate sense operation.

To avoid issues caused by the leakage current of transistors, and realize other benefits, the memory cells in a memory array 155 may include non-volatile gain memory cells as described herein. For example, the memory cells may include a ferroelectric material positioned within the memory cell so that a logic state can be stored by modifying the capacitance of the ferroelectric material. Because the logic state is represented by the capacitance of the ferroelectric material rather than the voltage level of the floating gate, the logic state may be impervious to transistor leakage current. Thus, the memory cell may be effectively non-volatile in that the logic state can be stored for long periods of time (e.g., on the order of years) without refreshing. As described herein, such a memory cell may provide additional advantages, such as non-destructive reads (e.g., because reading the memory cell does not modify the capacitance of the ferroelectric memory cell) and intrinsic amplification (e.g., the output of signals with large enough differences that amplification is unnecessary for sensing).

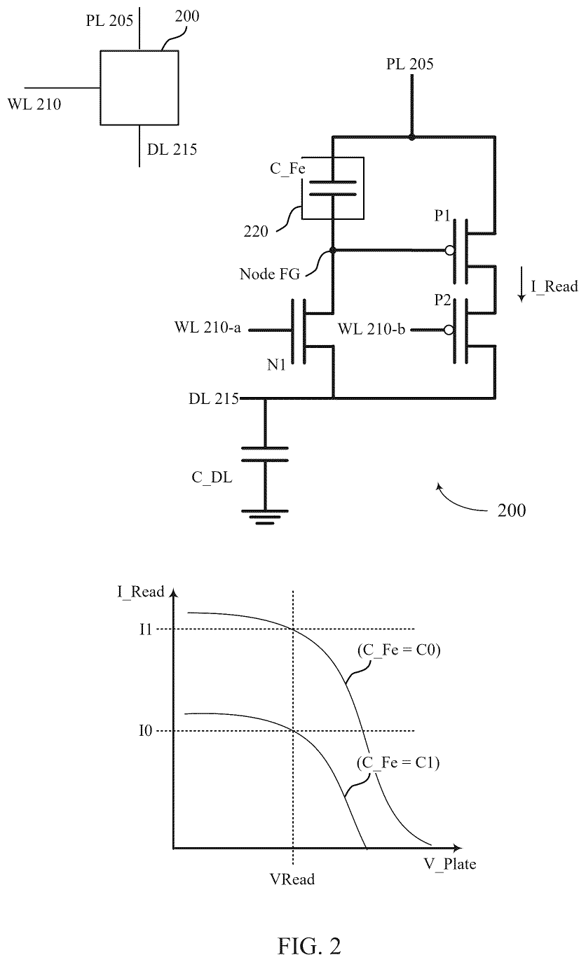

FIG. 2 illustrates an example of non-volatile gain memory cell 200 in accordance with examples as disclosed herein. The memory cell 200 may be an example of a memory cell included in a memory array 155 as described with reference to FIG. 1. The memory cell 200 may be coupled with, and accessed using, a plate line (PL) 205, a digit line (DL) 215, and one or more word lines (WLs) 210. The memory cell 200 may include a ferroelectric material 220 between the plate line 205 and the transistor N1. The ferroelectric material 220 may have a configurable capacitance (denoted C_Fe) that is modified to represent a logic state during a write operation and that controls the amplitude of the signal outputted on the digit line during a read operation. In some examples, the ferroelectric material 220 be, or be included, a ferroelectric capacitor.

The memory cell 200 may be written with a logic state by applying a voltage difference across the ferroelectric material 220. For example, a first logic state may be written to the memory cell 200 by applying a first voltage difference (e.g., −1 V) across the ferroelectric material 220, and a second logic state may be written to the memory cell 200 by applying a second voltage difference (e.g., +1 V) across the ferroelectric material 220. The voltage difference may be applied by concurrently biasing the plate line 205 and the digit line 215. Application of the voltage difference may modify the polarization of the ferroelectric material 220 (and therefore the capacitance C_Fe of the ferroelectric material 220) so that the capacitance C_Fe of the ferroelectric material 220 is representative of the logic state. For example, application of the voltage difference may configure the ferroelectric material 220 with a high capacitance (e.g., C_Fe=C1) or a low capacitance (e.g., C_Fe=C0). During the write operation, transistor N1 may be activated whereas transistor P1 and P2, which may be p-type transistors, may be deactivated. In some examples, the digit line 215 may have a capacitance C_DL.

Because the logic state is represented by the capacitance of the ferroelectric material (e.g., instead of being represented by charge on the node FG), the logic state may persist over long periods of time despite the leakage current of the transistor N1 (or other transistors). Thus, the memory cell 200 may be considered to be a non-volatile memory cell that is capable of retaining a stored logic state for long durations of time (e.g., on the order of years) without refresh (e.g., re-writing the logic state to the memory cell). Additionally, the memory cell 200 may be written faster than other non-volatile memory cells, such as NAND cells, because the memory cell 200 is writable using a single write operation (e.g., as opposed to multiple write and/or verify operations).

The memory cell 200 may be configured to support a write operation as described herein. So, in the memory cell 200, the ferroelectric material 220 may be between, and coupled with, the plate line 205 and the transistor N1, which may be an example of n-type transistor (in some cases). For example, if the ferroelectric material 220 is a ferroelectric capacitor, a first terminal of the ferroelectric material may be coupled with the plate line 205 and a first terminal of the transistor P1, and a second terminal of the ferroelectric capacitor may be coupled with the gate terminal of the transistor P1 and the transistor N1. Additionally, the transistor N1 may be coupled with the digit line 215 and the word line 210-a. For example, a first terminal of the transistor N1 may be coupled with the ferroelectric material 220 and the transistor P1, a second terminal of the transistor N1 may be coupled with the digit line 215, and the gate terminal of the transistor N1 may be coupled with the word line 210-a.

The logic state stored by the memory cell 200 may be read by biasing the memory cell 200 so that a signal representative of the logic state is outputted onto the digit line 215. For example, the logic state stored by the memory cell 200 may be read by deactivating the transistor N1, activating the transistor P2, and applying a voltage V_Plate to the plate line 205. The activation of the transistor P1, and thus the amplitude of the signal outputted onto the digit line 215, may be controlled by the voltage on node FG (denoted V_FG), which in turn may be based on the capacitance C_Fe of the ferroelectric material 220. For example, the ferroelectric material 220 and the capacitance C_FG of the node FG (which may be static) may form a capacitive voltage divider such that the voltage on the node FG varies with the capacitance of the ferroelectric material (e.g., the voltage on the node FG may be based on a ratio of the capacitance C_Fe and the capacitance C_FG).

So, application of voltage to the plate line 205 may cause the voltage on the node FG to increase, but the amount by which the voltage on the node FG increases may be based on (e.g., a function of) the capacitance C_Fe of the ferroelectric material 220. For instance, if the capacitance C_Fe of the ferroelectric material 220 is low (e.g., C_Fe=C0), the voltage on the node FG may be relatively low (e.g., V_FG=VLow). Accordingly, the transistor P1 may be at least partially activated (e.g., to a first activation level) and a relatively high level of current (e.g., I_Read=I1 for V_Plate=VRead) may flow through the transistor P1 and the transistor P2 to the digit line 215. If the capacitance C_Fe of the ferroelectric material 220 is high (e.g., C_Fc=C1), the voltage on the node FG may be relatively high (e.g., V_FG=VHigh). Accordingly, the transistor P1 may be deactivated (or partially activated to a second activation level lower than the first activation level) and a relatively low level of current (e.g., I_Read=I0 for V_Plate=VRead) may flow through the transistor P1 and the transistor P2 to the digit line 215.

Although described with reference to activation or deactivation of the transistor P1, the activation status of the transistor P1 may be on a spectrum or continuum. For example, the transistor P1 may be considered activated if the channel of the transistor P1 is open to allow current to flow such that the transistor P1 acts as a switch. And the transistor P1 may be considered deactivated if the channel of the transistor P1 is closed such that current is unable to flow. The transistor P1 may be considered as partially activated if the channel of the transistor P1 is partially open such that the transistor P1 allows a lesser amount of current to flow than in the activated state but more than in the deactivated state. The activation level of a partially activated transistor P1 may refer to the amount of current allowed to flow through the partially open channel, where higher activation levels correspond to higher levels of current flow.

The bottom figure shows an example of the current outputted by the memory cell 200 (e.g., onto the digit line 215) when the voltage applied to the plate line 205 (V_Plate) is equal to Vread. If the memory cell 200 is configured with C_Fe=C0, the current outputted by the memory cell 200 onto the digit line 215 may be equal to I1. If the memory cell 200 is configured with C_Fe=C1, the current outputted by the memory cell 200 onto the digit line 215 may be equal to I0. The magnitude of the difference between I0 and I1 may large enough (e.g., 100×, 1000×) that the signal can be sensed accurately without amplification. Thus, the memory cell 200 may be said to provide intrinsic amplification.

Due to the design and operation of the memory cell 200, the read operation may not destroy or modify capacitance C_Fe of the ferroelectric material 220. That is, the read operation may not be destructive. Accordingly, use of the memory cell 200 in an array 155 may allow the memory system to omit write-back circuitry (e.g., circuitry that is configured to restore the logic state of a memory cell after a destructive read).

The memory cell 200 may be configured to support a read operation as described herein. So, in the memory cell 200, a first terminal of the transistor P1 may be coupled with the plate line 205 (and with the ferroelectric material 220), a second terminal of the transistor P1 may be coupled with the transistor P2, and the gate terminal of the transistor P1 may be coupled with the node FG, which may be between the ferroelectric material 220 and the transistor N1. A first terminal of the transistor P2 may be coupled with the transistor P1, a second terminal of the transistor P2 may be coupled with the digit line 215 (and the transistor N1), and the gate terminal of the transistor P2 may be coupled with the word line 210-b. In some examples, the word line 210-a and the word line 210-b may be the same word line (e.g., the gate terminal of the transistor N1 may be coupled with the gate terminal of the transistor P2). In other examples, the word line 210-a and the word line 210-b may be different word lines (e.g., the gate terminal of the transistor N1 may be isolated from the gate terminal of the transistor P2).

Thus, the memory cell 200 may store a logic state by setting the capacitance of the ferroelectric material 220 to level that is representative of the logic state.

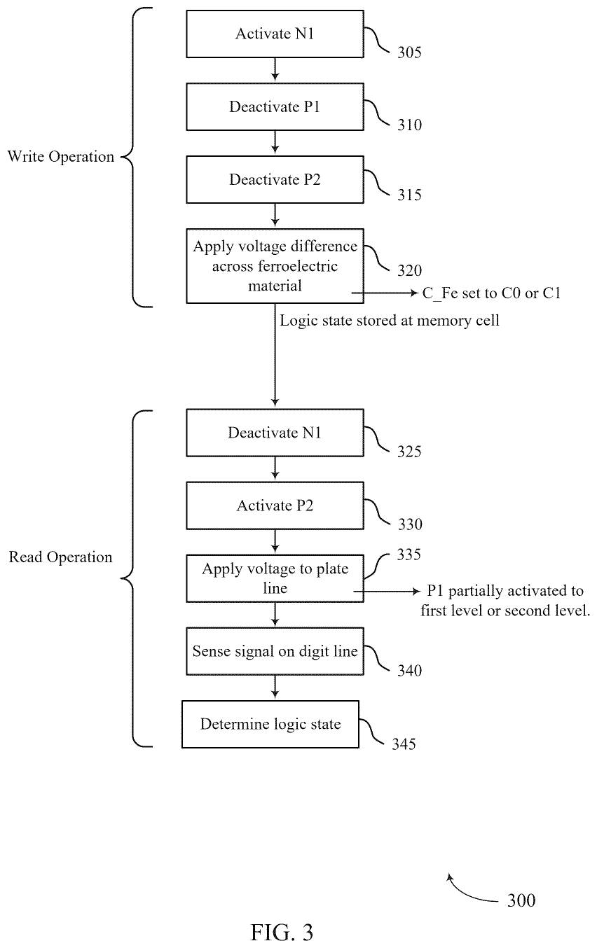

FIG. 3 shows an example of a process flow 300 that supports operation of a non-volatile gain memory cell in accordance with examples as disclosed herein. The memory cell may be an example of the memory cell 200 as described herein. The memory cell may be written with a logic state using steps 305 through 320 of a write operation and may be read using steps 315 through 345 of a read operation. Writing the memory cell 200 may include setting the capacitance C_Fe of the ferroelectric material 220 to a level representative of the logic state and reading the memory cell 200 may include sensing a signal whose magnitude is based on (e.g., a function of) the capacitance C_Fe of the ferroelectric material 220.

The write operation to write the memory cell 200 with a logic state (e.g., a logic 0 or a logic 1) may include steps 305 through 320. At 305, the transistor N1 may be activated (e.g., by applying a sufficiently high voltage to the gate terminal of the transistor N1 through the word line 210-a). The transistor N1 may be activated so that a voltage on node FG develops when a voltage is applied to the digit line 215. At 310, the transistor P2 may be deactivated (e.g., by applying a sufficiently high voltage to the gate terminal of the transistor P1 through the word line 210-b). In some examples, the word line 210-a and the word line 210-b are the same word line. In some examples, the transistor N1 is activated concurrently (e.g., at wholly or partially overlapping times) with deactivating the transistor P2. At 315, the transistor P1 may be deactivated. So, after 315, the transistor N1 may be activated and the transistor P1 and the transistor P2 may each be deactivated.

At 320, a voltage difference may be applied across the ferroelectric material 220. The voltage difference may be applied by applying a first voltage to the plate line 205 and by applying a second voltage to the digit line 215. The magnitude, polarity, or both of the voltage difference may be based on the logic state to be written to the memory cell 200. For example, the voltage difference may be equal to VDIFF_0 if a logic 0 is to be written to the memory cell 200 and may be equal to VDIFF_1 if a logic 1 is to be written to the memory cell 200. Application of the voltage difference across the ferroelectric material 220 may modify the polarization, and thus the capacitance C_Fe, of the ferroelectric material 220. For example, application of the voltage difference may configure the ferroelectric material 220 with a capacitance equal to C0 or C1. Thus, after 320, the logic state may be stored at the memory cell 200 in the form of the capacitance C_Fe of the ferroelectric material 220.

The read operation to read logic state from the memory cell 200 may include steps 325 through 345. At 325, the transistor N1 may be deactivated (e.g., by applying a sufficiently low voltage to the gate terminal of the transistor N1 through the word line 210-a). At 330, the transistor P2 may be activated (e.g., by applying a sufficiently low voltage to the gate terminal of the transistor P2 through the word line 210-b). In some examples, the word line 210-a and the word line 210-b are the same word line. In some examples, the transistor N1 is deactivated concurrently (e.g., at wholly or partially overlapping times) with activating the transistor P2.

At 335, a voltage may be applied to the plate line 205. For example, the voltage VRead may be applied to the plate line 205. A voltage on the node FG (e.g., V_FG) may develop based on the voltage applied to the plate line 205 and based on the capacitance C_Fe of the ferroelectric material 220. For example, the level of the voltage on node FG may be based on the ratio of C_Fe to C_FG, where C_FG may be fixed. So, the voltage on node FG may vary with the capacitance C_Fe of the ferroelectric material 220. For instance, the voltage on node FG may be a first level (e.g., V_FG=VLow) if the capacitance C_Fe of the ferroelectric material 220 is low (e.g., if C_Fe=C0) and may be a second level (e.g., V_FG=VHigh) if the capacitance C_Fe of the ferroelectric material 220 is high (e.g., if C_Fe=C1).

In response to applying the voltage to the plate line 205, current may flow through the transistor P1 and the transistor P2. The amount of current that flows through the transistor P1 and the transistor P2 may be based on the activation level of the transistor P1, which in turn may be based on the voltage of the node FG. For example, the transistor P1, which is activatable based on the voltage of the node FG, may be activated to a first level (e.g., a relatively high level) if C_Fe=C0 (because V_FG=VLow) and a relatively high level of current may flow through the transistor P1 and the transistor P2 to the digit line 215. If C_Fe=C1, the transistor P1 may be activated to a second level (e.g., a relatively low level) (because V_FG=VHigh) and a relatively low level of current may flow through the transistor P1 and the transistor P2 to the digit line 215.

At 340, the signal on the digit line 215 may be sensed (e.g., by a sense component). In some examples, the signal sensed at 340 may be the current outputted by the memory cell 200 onto the digit line 215. In other examples, the signal sensed at 340 may be a voltage of the digit line 215. In any event, the amplitude of the signal may represent the logic state stored by the memory cell 200. Thus, at 345, the logic state stored by the memory cell 200 may be determined.

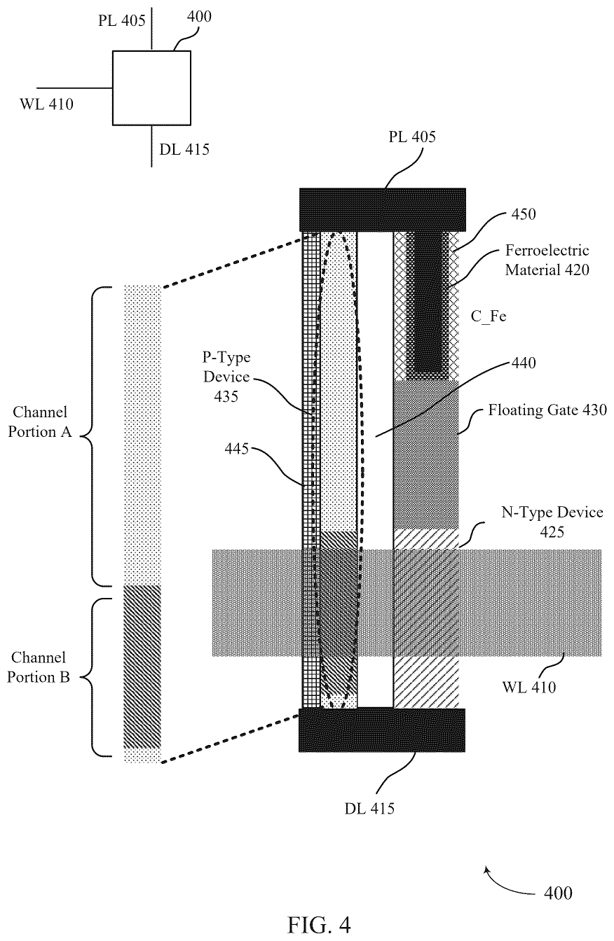

FIG. 4 shows an example of a non-volatile gain memory cell 400 in accordance with examples as disclosed herein. The memory cell 400 may be an example of a memory cell that stores a logic state by using the capacitance of a ferroelectric material to represent the logic state. The memory cell 400 may be formed of various materials and devices and may be an example of the memory cell 200 described with reference to FIG. 2. Accordingly, the memory cell 400 may have similar properties and characteristics as the memory cell 200, such a non-volatility, non-destructive reads, and intrinsic amplification.

The memory cell 400 may be an example of a memory cell included in a memory array 155 as described with reference to FIG. 1. The memory cell 400 may be coupled with, and accessed using, a plate line (PL) 405, a digit line (DL) 415, and one or more word lines (WLs) 410. The memory cell 400 may include a ferroelectric material 420 coupled with (and between) the plate line 405 and the floating gate 430, which may be a block of conductive material (e.g., metal). In some examples, the ferroelectric material 420 maybe in direct contact with (e.g., touching) the plate line 405 and the floating gate 430. Together, these components may act as a ferroelectric capacitor (e.g., the plate line 405 may serve as one electrode of the ferroelectric capacitor and the floating gate 430 may serve as the other electrode of the ferroelectric capacitor). The ferroelectric material 420 may have a configurable capacitance (denoted C_Fe) that is modified to represent a logic state during a write operation and that controls the amplitude of the signal outputted on the digit line 415 during a read operation.

The memory cell 400 may also include an n-type device 425, which in some examples may be or include an n-type transistor or an n-type material. The n-type device 425 may include a gate portion that is coupled with the word line 410 and that controls the activation level of the n-type device 425. The n-type device 425 may be coupled with (and in some cases may directly contact) the floating gate 430. The n-type device 425 may also be coupled with (and in some cases may directly contact) the digit line 415. The word line 410 may overlay the n-type device 425 and the p-type device 435 (as opposed to traversing through the n-type device 425 and the p-type device 435).

The memory cell 400 may also include a p-type device 435, which in some examples may be or include a p-type transistor or a p-type material. The p-type device 435 may include gate portion that is coupled with the word line 410 and that controls the activation level of a first channel portion (e.g., channel portion B) of the p-type device 435. The p-type device 435 may also include a second channel portion (e.g., channel portion A) whose activation level is controlled by the voltage on the floating gate 430.

In some examples, the p-type device 435 is physically separated from the n-type device 425 and the floating gate 430 by separation or filler material 440. In some examples, the p-type device 435 may be at least partially surrounded by, in direct contact with, or both, a separation or filler material 445. In some examples, the ferroelectric material 420 may be at least partially surrounded by, in direct contact with, or both, a separation or filler material 450.

The memory cell 400 may be written with a logic state by applying a voltage difference across the ferroelectric material 420. For example, a first logic state may be written to the memory cell 400 by applying a first voltage difference (e.g., −1 V) across the ferroelectric material 420, and a second logic state may be written to the memory cell 400 by applying a second voltage difference (e.g., +1 V) across the ferroelectric material 420. The voltage difference may be applied by concurrently biasing the plate line 405 and the digit line 415.

Application of the voltage difference may modify the polarization of the ferroelectric material 420 (and therefore the capacitance C_Fe of the ferroelectric material 420) so that the capacitance C_Fe of the ferroelectric material 420 is representative of the logic state. For example, application of the voltage difference may configure the ferroelectric material 420 with a high capacitance (e.g., C_Fe=C1) or a low capacitance (e.g., C_Fe=C0). During the write operation, the n-type device 425 may be activated whereas the p-type device 435 may be deactivated. For example, a voltage applied to the word line 410 may activate the n-type device 425 and may deactivate the p-type device 435. Although shown coupled with the same word line 410, the n-type device 425 and the p-type device 435 may be coupled with different word lines.

The logic state stored by the memory cell 400 may be read by applying a voltage V_Plate to the plate line 405, deactivating the n-type device 425, and activating channel portion B of the p-type device 435. The activation of channel portion A of the p-type device 435, and thus the amplitude of the signal outputted onto the digit line 415, may be controlled by the voltage on the floating gate 430 (denoted V_FG), which in turn may be based on the capacitance C_Fe of the ferroelectric material 420. For example, the ferroelectric material 420 and the capacitance C_FG of floating gate 430 may form a capacitive voltage divider such that the voltage on the floating gate 430 varies with the capacitance of the ferroelectric material (e.g., the voltage on the floating gate 430 may be based on a ratio of the capacitance C_Fe and the capacitance C_FG).

So, application of voltage to the plate line 405 may cause the voltage on the floating gate 430 to increase, but the amount by which the voltage on the floating gate 430 increases may be based on (e.g., a function of) the capacitance C_Fe of the ferroelectric material 420. For instance, if the capacitance C_Fe of the ferroelectric material 420 is low (e.g., C_Fe=C0), the voltage on the floating gate 430 may be relatively low (e.g., V_FG=VLow). Accordingly, channel portion A of the p-type device 435 may be at least partially activated (e.g., to a first activation level) and a relatively high level of current may flow through the p-type device 435 to the digit line 415. If the capacitance C_Fe of the ferroelectric material 420 is high (e.g., C_Fe=C1), the voltage on the floating gate 430 may be relatively high (e.g., V_FG=VHigh). Accordingly, channel portion A of the p-type device 435 may be deactivated (or partially activated to a second activation level lower than the first activation level) and a relatively low level of current may flow through the p-type device 435 to the digit line 415. So, channel portion A may be activatable by the voltage on the floating gate 430 due to the proximity between channel portion A and the floating gate 430, even though channel portion A and the floating gate 430 are not physically coupled (e.g., in direct contact, touching). In some examples, channel portion A and floating gate 430 may be referred to as being inductively coupled in that a changing voltage on the floating gate 430 may induce an electrical response on channel portion A.

The activation status of channel portion A may be on a spectrum or continuum. For example, channel portion A may be considered activated (e.g., open) if current flows through channel portion A such that the p-type device 435 acts as a switch. And channel portion A may be considered deactivated (e.g., closed) if current is unable to flow through channel portion A. Channel portion A may be considered as partially activated (e.g., partially open) if a lesser amount of current flows through channel portion A than in the activated state but more than in the deactivated state. The activation level of a partially activated channel portion may refer to the amount of current allowed to flow through the partially open channel, where higher activation levels correspond to higher levels of current flow.

Thus, the memory cell 400 may store a logic state by configuring (e.g., setting) the capacitance of the ferroelectric material 420 to level that is representative of the logic state.

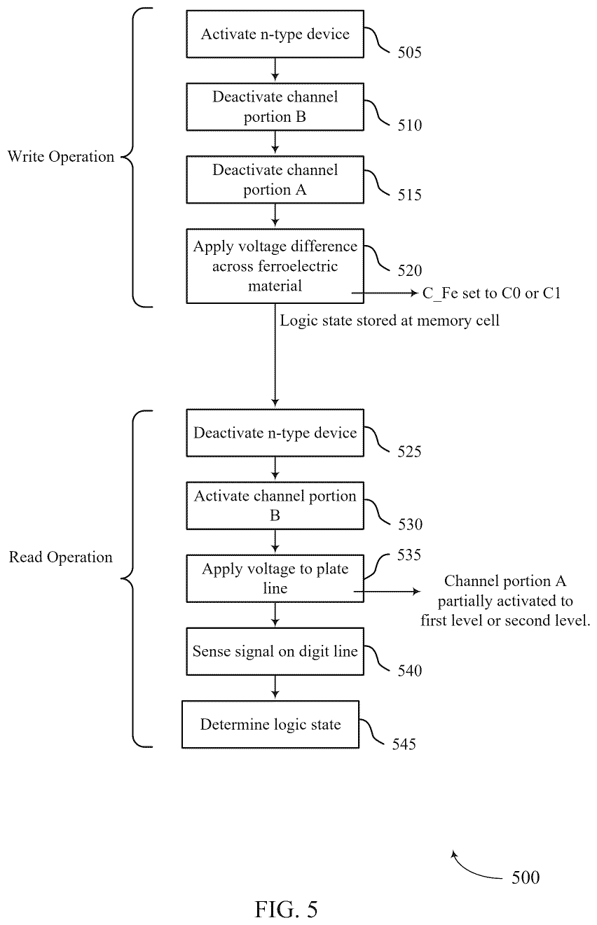

FIG. 5 shows an example of a process flow 500 that supports operating a non-volatile gain memory cell in accordance with examples as disclosed herein. The memory cell may be an example of the memory cell 400 as described herein. The memory cell may be written with a logic state using steps 505 through 520 of a write operation and may be read using steps 515 through 545 of a read operation. Writing the memory cell 400 may include modifying the capacitance C_Fe of the ferroelectric material 420 to a level representative of the logic state and reading the memory cell 400 may include sensing a signal whose magnitude is based on (e.g., a function of) the capacitance C_Fe of the ferroelectric material 420.

The write operation to write the memory cell 400 with a logic state (e.g., a logic 0 or a logic 1) may include steps 505 through 520. At 505, the n-type device 425 may be activated (e.g., by applying a sufficiently high voltage to the gate portion of the n-type device through the word line 410). The n-type device 425 may be activated so that a voltage on the floating gate 430 develops when a voltage is applied to the digit line 415.

At 510, channel portion B of the p-type device 435 may be deactivated (e.g., by applying a sufficiently high voltage to the gate portion of the p-type device 435 through the word line 410). In some examples, the n-type device 425 is activated concurrently (e.g., at wholly or partially overlapping times) with deactivating channel portion B of the p-type device 435. At 515, channel portion A of the p-type device 435 may be deactivated. So, after 515, the n-type device 425 may be activated and both channel portions (e.g., channel portion A, channel portion B) of the p-type device 435 may be deactivated.

At 520, a voltage difference may be applied across the ferroelectric material 420. The voltage difference may be applied by applying a first voltage to the plate line 405 and by applying a second voltage to the digit line 415. The magnitude, polarity, or both of the voltage difference may be based on the logic state to be written to the memory cell 400. For example, the voltage difference may be equal to VDIFF_0 if a logic 0 is to be written to the memory cell 400 and may be equal to VDIFF_1 if a logic 1 is to be written to the memory cell 400. Application of the voltage difference across the ferroelectric material 420 may modify the polarization, and thus the capacitance C_Fe, of the ferroelectric material 420. For example, application of the voltage difference may configure the ferroelectric material 420 with a capacitance equal to C0 or C1. Thus, after 420, the logic state may be stored at the memory cell 400 in the form of the capacitance C_Fe of the ferroelectric material 420.

The read operation to read logic state from the memory cell 400 may include steps 525 through 545. At 525, the n-type device 425 may be deactivated (e.g., by applying a sufficiently low voltage to the gate portion of the n-type device 425 through the word line 410). At 530, channel portion B of the p-type device 435 may be activated (e.g., by applying a sufficiently low voltage to the gate portion of the p-type device through the word line 410). In some examples, the n-type device 425 is deactivated concurrently (e.g., at wholly or partially overlapping times) with activating channel portion B of the p-type device 435.

At 535, a voltage may be applied to the plate line 405. For example, the voltage VRead may be applied to the plate line 405. A voltage on the floating gate 430 (e.g., V_FG) may develop based on the voltage applied to the plate line 405 and based on the capacitance C_Fe of the ferroelectric material 420. For example, the level of the voltage on the floating gate 430 may be based on the ratio of C_Fe to C_FG, where C_FG may be fixed. So, the voltage on the floating gate may vary with the capacitance C_Fe of the ferroelectric material 420. For instance, the voltage on the floating gate 430 may be a first level (e.g., V_FG=VLow) if the capacitance C_Fe of the ferroelectric material 420 is low (e.g., if C_Fe=C0) and may be a second level (e.g., V_FG=VHigh) if the capacitance C_Fe of the ferroelectric material 420 is high (e.g., if C_Fe=C1).

In response to applying the voltage to the plate line 405, current may flow through the p-type device 435. The amount of current that flows through the p-type device 435 may be based on the activation level of channel portion A, which in turn may be based on the voltage of the floating gate 430. For example, channel portion A, which is activatable based on the voltage of the floating gate 430, may be activated to a first level (e.g., a relatively high level) if C_Fe=C0 (because V_FG=VLow) and a relatively high level of current may flow through the p-type device 435 to the digit line 415. If C_Fe=C1, channel portion B may be activated to a second level (e.g., a relatively low level) (because V_FG=VHigh) and a relatively low level of current may flow through the p-type device 435 to the digit line 415.

At 540, the signal on the digit line 415 may be sensed (e.g., by a sense component). In some examples, the signal sensed at 540 may be the current outputted by the memory cell 400 (e.g., through the p-type device 435) onto the digit line 415. In other examples, the signal sensed at 540 may be a voltage of the digit line 415. In any event, the amplitude of the signal may represent the logic state stored by the memory cell 400. Thus, at 545, the logic state stored by the memory cell 400 may be determined.

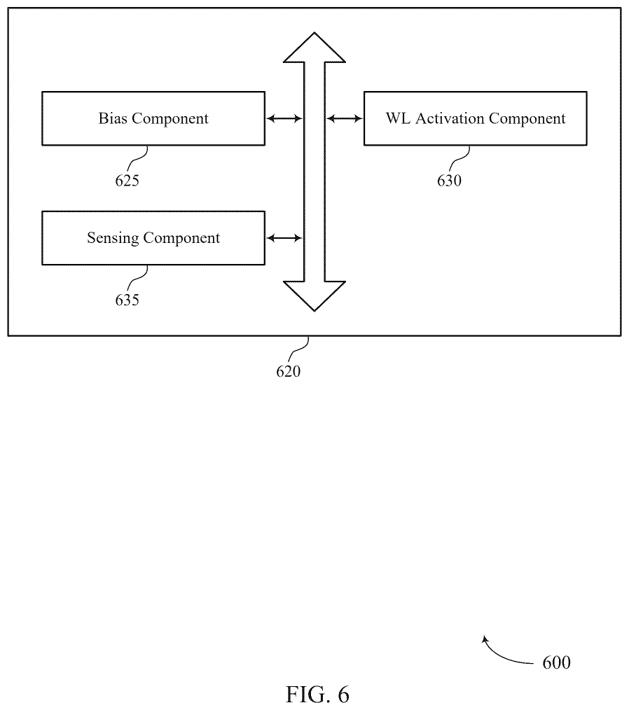

FIG. 6 shows a block diagram 600 of a memory system 620 that supports a non-volatile gain memory cell in accordance with examples as disclosed herein. The memory system 620 may be an example of aspects of a memory system as described with reference to FIGS. 1 through 5. The memory system 620, or various components thereof, may be an example of means for performing various aspects of a non-volatile gain memory cell as described herein. For example, the memory system 620 may include a bias component 625, a WL activation component 630, a sensing component 635, or any combination thereof. Each of these components, or components of subcomponents thereof (e.g., one or more processors, one or more memories), may communicate, directly or indirectly, with one another (e.g., via one or more buses).

The bias component 625 may be configured as or otherwise support a means for deactivating a first p-type transistor, where the first p-type transistor includes a gate terminal coupled with a node between a ferroelectric material and an n-type transistor and is activatable based at least in part on a capacitance of the ferroelectric material. The WL activation component 630 may be configured as or otherwise support a means for deactivating a second p-type transistor, where the second p-type transistor includes a gate terminal coupled with a word line and is activatable based at least in part on a voltage of the word line. In some examples, the WL activation component 630 may be configured as or otherwise support a means for activating the n-type transistor, where the n-type transistor is coupled with the ferroelectric material and a digit line. In some examples, the bias component 625 may be configured as or otherwise support a means for applying a voltage difference across the ferroelectric material based at least in part on activating the n-type transistor and based at least in part on a logic state, where the capacitance of the ferroelectric material is based at least in part on the voltage difference and is representative of the logic state.

In some examples, the n-type transistor is activatable based at least in part on the voltage of the word line. In some examples, the bias component 625 may be configured as or otherwise support a means for applying a first voltage to a plate line coupled with the ferroelectric material. In some examples, the bias component 625 may be configured as or otherwise support a means for applying a second voltage to the digit line concurrent with applying the first voltage to the plate line, where the voltage difference is applied across the ferroelectric material based at least in part on applying the first voltage and the second voltage.

In some examples, a first terminal of the first p-type transistor is coupled with a plate line of the memory cell. In some examples, a second terminal of the first p-type transistor is coupled with the second p-type transistor.

In some examples, a first terminal of the second p-type transistor is coupled with the first p-type transistor. In some examples, a second terminal of the second p-type transistor is coupled with the digit line and the n-type transistor.

In some examples, a first terminal of the n-type transistor is coupled with the ferroelectric material, the node, and the gate terminal of the first p-type transistor. In some examples, a second terminal of the n-type transistor is coupled with the digit line and the second p-type transistor.

In some examples, the WL activation component 630 may be configured as or otherwise support a means for deactivating an n-type transistor coupled with a ferroelectric material and a digit line. In some examples, the WL activation component 630 may be configured as or otherwise support a means for activating a first p-type transistor including a gate terminal coupled with a word line. In some examples, the bias component 625 may be configured as or otherwise support a means for applying a voltage to a plate line coupled with the ferroelectric material and with a second p-type transistor that includes a gate terminal coupled with a node between the n-type transistor and the ferroelectric material, where a voltage that is based at least in part on a capacitance of the ferroelectric material develops on the node based at least in part on applying the voltage to the plate line. The sensing component 635 may be configured as or otherwise support a means for sensing a signal on the digit line based at least in part on applying the voltage to the plate line, where a magnitude of the signal is based at least in part on the voltage on the node.

In some examples, an activation level of the second p-type transistor is based at least in part on the voltage on the node. In some examples, the signal on the digit line is based at least in part on the activation level of the second p-type transistor.

In some examples, the signal includes a current that flows through the first p-type transistor and the second p-type transistor. In some examples, the n-type transistor is deactivated concurrently with activating the first p-type transistor.

In some examples, a gate terminal of the n-type transistor is coupled with the word line. In some examples, the n-type transistor is activatable based at least in part on a voltage of the word line.

In some examples, a first terminal of the n-type transistor is coupled with the ferroelectric material, the node, and the gate terminal of the second p-type transistor. In some examples, a second terminal of the n-type transistor is coupled with the digit line and the first p-type transistor.

In some examples, a first terminal of the first p-type transistor is coupled with the second p-type transistor. In some examples, a second terminal of the first p-type transistor is coupled with the digit line and the n-type transistor.

In some examples, a first terminal of the second p-type transistor is coupled with the plate line. In some examples, a second terminal of the second p-type transistor is coupled with the first p-type transistor.

In some examples, the described functionality of the memory system 620, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 620, or various components thereof, may be implemented at least in part by instructions (e.g., stored in memory, non-transitory computer-readable medium) executable by such at least one processor.

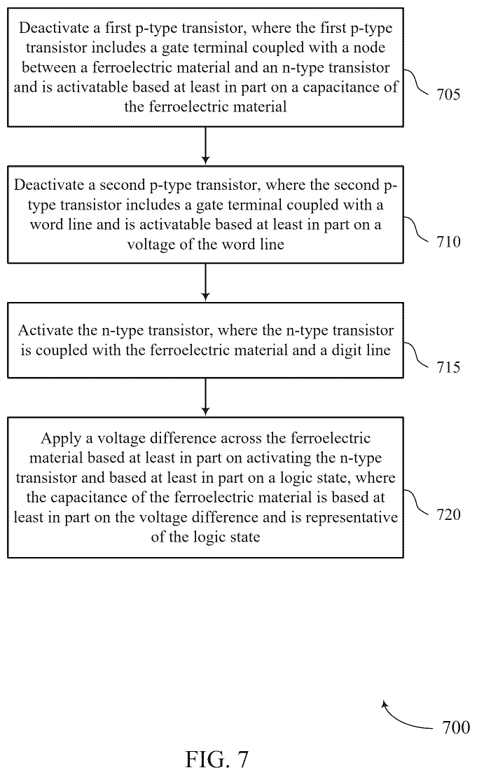

FIG. 7 shows a flowchart illustrating a method 700 that supports a non-volatile gain memory cell in accordance with examples as disclosed herein. The operations of method 700 may be implemented by a memory system or its components as described herein. For example, the operations of method 700 may be performed by a memory system as described with reference to FIGS. 1 through 6. In some examples, a memory system may execute a set of instructions to control the functional elements of the device to perform the described functions. Additionally, or alternatively, the memory system may perform aspects of the described functions using special-purpose hardware.

At 705, the method may include deactivating a first p-type transistor (e.g., transistor P1), where the first p-type transistor includes a gate terminal coupled with a node between a ferroelectric material (e.g., ferroelectric material 220) and an n-type transistor (e.g., transistor N1) and is activatable based at least in part on a capacitance of the ferroelectric material. In some examples, aspects of the operations of 705 may be performed by a bias component 625 as described with reference to FIG. 6.

At 710, the method may include deactivating a second p-type transistor (e.g., transistor P2), where the second p-type transistor includes a gate terminal coupled with a word line (e.g., word line 210-b) and is activatable based at least in part on a voltage of the word line. In some examples, aspects of the operations of 710 may be performed by a WL activation component 630 as described with reference to FIG. 6.

At 715, the method may include activating the n-type transistor, where the n-type transistor is coupled with the ferroelectric material and a digit line (e.g., digit line 215). In some examples, aspects of the operations of 715 may be performed by a WL activation component 630 as described with reference to FIG. 6.

At 720, the method may include applying a voltage difference across the ferroelectric material based at least in part on activating the n-type transistor and based at least in part on a logic state, where the capacitance of the ferroelectric material is based at least in part on the voltage difference and is representative of the logic state. In some examples, aspects of the operations of 720 may be performed by a bias component 625 as described with reference to FIG. 6.

In some examples, an apparatus as described herein may perform a method or methods, such as the method 700. The apparatus may include features, circuitry, logic, means, or instructions (e.g., a non-transitory computer-readable medium storing instructions executable by a processor), or any combination thereof for performing the following aspects of the present disclosure:
Aspect 1: A method, apparatus, or non-transitory computer-readable medium including operations, features, circuitry, logic, means, or instructions, or any combination thereof for deactivating a first p-type transistor, where the first p-type transistor includes a gate terminal coupled with a node between a ferroelectric material and an n-type transistor and is activatable based at least in part on a capacitance of the ferroelectric material; deactivating a second p-type transistor, where the second p-type transistor includes a gate terminal coupled with a word line and is activatable based at least in part on a voltage of the word line; activating the n-type transistor, where the n-type transistor is coupled with the ferroelectric material and a digit line; and applying a voltage difference across the ferroelectric material based at least in part on activating the n-type transistor and based at least in part on a logic state, where the capacitance of the ferroelectric material is based at least in part on the voltage difference and is representative of the logic state.
Aspect 2: The method, apparatus, or non-transitory computer-readable medium of aspect 1, where the n-type transistor is activatable based at least in part on the voltage of the word line.
Aspect 3: The method, apparatus, or non-transitory computer-readable medium of any of aspects 1 through 2, further including operations, features, circuitry, logic, means, or instructions, or any combination thereof for applying a first voltage to a plate line coupled with the ferroelectric material and applying a second voltage to the digit line concurrent with applying the first voltage to the plate line, where the voltage difference is applied across the ferroelectric material based at least in part on applying the first voltage and the second voltage.
Aspect 4: The method, apparatus, or non-transitory computer-readable medium of any of aspects 1 through 3, where a first terminal of the first p-type transistor is coupled with a plate line of the memory cell and a second terminal of the first p-type transistor is coupled with the second p-type transistor.
Aspect 5: The method, apparatus, or non-transitory computer-readable medium of

any of aspects 1 through 4, where a first terminal of the second p-type transistor is coupled with the first p-type transistor and a second terminal of the second p-type transistor is coupled with the digit line and the n-type transistor.
Aspect 6: The method, apparatus, or non-transitory computer-readable medium of any of aspects 1 through 5, where a first terminal of the n-type transistor is coupled with the ferroelectric material, the node, and the gate terminal of the first p-type transistor and a second terminal of the n-type transistor is coupled with the digit line and the second p-type transistor.

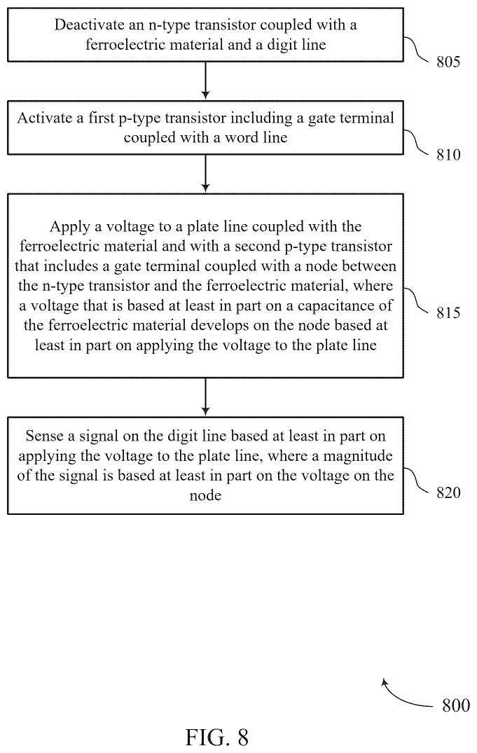

FIG. 8 shows a flowchart illustrating a method 800 that supports a non-volatile gain memory cell in accordance with examples as disclosed herein. The operations of method 800 may be implemented by a memory system or its components as described herein. For example, the operations of method 800 may be performed by a memory system as described with reference to FIGS. 1 through 6. In some examples, a memory system may execute a set of instructions to control the functional elements of the device to perform the described functions. Additionally, or alternatively, the memory system may perform aspects of the described functions using special-purpose hardware.

At 805, the method may include deactivating an n-type transistor (e.g., transistor N1) coupled with a ferroelectric material (e.g., ferroelectric material 220) and a digit line (e.g., digit line 215). In some examples, aspects of the operations of 805 may be performed by a WL activation component 630 as described with reference to FIG. 6.

At 810, the method may include activating a first p-type transistor (e.g., transistor P2) including a gate terminal coupled with a word line. In some examples, aspects of the operations of 810 may be performed by a WL activation component 630 as described with reference to FIG. 6.

At 815, the method may include applying a voltage to a plate line (e.g., plate line 205) coupled with the ferroelectric material and with a second p-type transistor (e.g., transistor P1) that includes a gate terminal coupled with a node (e.g., node FG) between the n-type transistor and the ferroelectric material, where a voltage that is based at least in part on a capacitance of the ferroelectric material develops on the node based at least in part on applying the voltage to the plate line. In some examples, aspects of the operations of 815 may be performed by a bias component 625 as described with reference to FIG. 6.

At 820, the method may include sensing a signal on the digit line based at least in part on applying the voltage to the plate line, where a magnitude of the signal is based at least in part on the voltage on the node. In some examples, aspects of the operations of 820 may be performed by a sensing component 635 as described with reference to FIG. 6.

In some examples, an apparatus as described herein may perform a method or methods, such as the method 800. The apparatus may include features, circuitry, logic, means, or instructions (e.g., a non-transitory computer-readable medium storing instructions executable by a processor), or any combination thereof for performing the following aspects of the present disclosure:
Aspect 7: A method, apparatus, or non-transitory computer-readable medium including operations, features, circuitry, logic, means, or instructions, or any combination thereof for deactivating an n-type transistor coupled with a ferroelectric material and a digit line; activating a first p-type transistor including a gate terminal coupled with a word line; applying a voltage to a plate line coupled with the ferroelectric material and with a second p-type transistor that includes a gate terminal coupled with a node between the n-type transistor and the ferroelectric material, where a voltage that is based at least in part on a capacitance of the ferroelectric material develops on the node based at least in part on applying the voltage to the plate line; and sensing a signal on the digit line based at least in part on applying the voltage to the plate line, where a magnitude of the signal is based at least in part on the voltage on the node.
Aspect 8: The method, apparatus, or non-transitory computer-readable medium of aspect 7, where an activation level of the second p-type transistor is based at least in part on the voltage on the node and the signal on the digit line is based at least in part on the activation level of the second p-type transistor.
Aspect 9: The method, apparatus, or non-transitory computer-readable medium of any of aspects 7 through 8, where the signal includes a current that flows through the first p-type transistor and the second p-type transistor.
Aspect 10: The method, apparatus, or non-transitory computer-readable medium of any of aspects 7 through 9, where the n-type transistor is deactivated concurrently with activating the first p-type transistor.
Aspect 11: The method, apparatus, or non-transitory computer-readable medium of any of aspects 7 through 10, where a gate terminal of the n-type transistor is coupled with the word line and the n-type transistor is activatable based at least in part on a voltage of the word line.
Aspect 12: The method, apparatus, or non-transitory computer-readable medium of any of aspects 7 through 11, where a first terminal of the n-type transistor is coupled with the ferroelectric material, the node, and the gate terminal of the second p-type transistor and a second terminal of the n-type transistor is coupled with the digit line and the first p-type transistor.
Aspect 13: The method, apparatus, or non-transitory computer-readable medium of any of aspects 7 through 12, where a first terminal of the first p-type transistor is coupled with the second p-type transistor and a second terminal of the first p-type transistor is coupled with the digit line and the n-type transistor.
Aspect 14: The method, apparatus, or non-transitory computer-readable medium of any of aspects 7 through 13, where a first terminal of the second p-type transistor is coupled with the plate line and a second terminal of the second p-type transistor is coupled with the first p-type transistor.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:
Aspect 15: A memory cell, including: a first transistor coupled with a digit line and including a gate terminal coupled with a word line; a ferroelectric material coupled with the first transistor and a plate line, and configured to have a capacitance that is based at least in part on a voltage difference between the plate line and the digit line; a second transistor coupled with the plate line and including a gate terminal coupled with a node between the ferroelectric material and the first transistor, the second transistor configured to be activated based at least in part on the capacitance of the ferroelectric material; and a third transistor coupled with the second transistor and the digit line, and including a gate terminal coupled with the word line.
Aspect 16: The memory cell of aspect 15, where the first transistor and the third transistor are each configured to be activated based at least in part on a voltage of the word line.
Aspect 17: The memory cell of any of aspects 15 through 16, where a first terminal of the first transistor is coupled with the ferroelectric material and a second terminal of the first transistor is coupled with the digit line and the third transistor.
Aspect 18: The memory cell of any of aspects 15 through 17, where the ferroelectric material includes a ferroelectric capacitor that includes a first terminal coupled with the plate line, and that includes a second terminal coupled with the first transistor and the gate terminal of the second transistor.
Aspect 19: The memory cell of any of aspects 15 through 18, where a first terminal of the second transistor is coupled with the plate line and the ferroelectric material, and a second terminal of the second transistor is coupled with the third transistor.
Aspect 20: The memory cell of any of aspects 15 through 19, where a first terminal of the third transistor is coupled with the second transistor, and a second terminal of the third transistor is coupled with the digit line and the first transistor.
Aspect 21: The memory cell of any of aspects 15 through 20, where: the first transistor includes an n-type transistor; the second transistor includes a first p-type transistor; and the third transistor includes a second p-type transistor.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, a wire, a conductive line, a conductive layer, or the like that provides a conductive path between components of a memory array.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory cell, comprising:
a first transistor coupled with a digit line and comprising a gate terminal coupled with a word line;
a ferroelectric material coupled with the first transistor and a plate line, and configured to have a capacitance that is based at least in part on a voltage difference between the plate line and the digit line;
a second transistor coupled with the plate line and comprising a gate terminal coupled with a node between the ferroelectric material and the first transistor, the second transistor configured to be activated based at least in part on the capacitance of the ferroelectric material; and
a third transistor coupled with the second transistor and the digit line, and comprising a gate terminal coupled with the word line.

2. The memory cell of claim 1, wherein the first transistor and the third transistor are each configured to be activated based at least in part on a voltage of the word line.

3. The memory cell of claim 1, wherein a first terminal of the first transistor is coupled with the ferroelectric material and a second terminal of the first transistor is coupled with the digit line and the third transistor.

4. The memory cell of claim 1, wherein the ferroelectric material comprises a ferroelectric capacitor that includes a first terminal coupled with the plate line, and that includes a second terminal coupled with the first transistor and the gate terminal of the second transistor.

5. The memory cell of claim 1, wherein:
a first terminal of the second transistor is coupled with the plate line and the ferroelectric material, and
a second terminal of the second transistor is coupled with the third transistor.

6. The memory cell of claim 1, wherein:
a first terminal of the third transistor is coupled with the second transistor, and
a second terminal of the third transistor is coupled with the digit line and the first transistor.

7. The memory cell of claim 1, wherein:
the first transistor comprises an n-type transistor;
the second transistor comprises a first p-type transistor; and
the third transistor comprises a second p-type transistor.

8. A method of writing a memory cell, comprising:
deactivating a first p-type transistor, wherein the first p-type transistor comprises a gate terminal coupled with a node between a ferroelectric material and an n-type transistor and is activatable based at least in part on a capacitance of the ferroelectric material;
deactivating a second p-type transistor, wherein the second p-type transistor comprises a gate terminal coupled with a word line and is activatable based at least in part on a voltage of the word line;
activating the n-type transistor, wherein the n-type transistor is coupled with the ferroelectric material and a digit line; and
applying a voltage difference across the ferroelectric material based at least in part on activating the n-type transistor and based at least in part on a logic state, wherein the capacitance of the ferroelectric material is based at least in part on the voltage difference and is representative of the logic state.

9. The method of claim 8, wherein the n-type transistor is activatable based at least in part on the voltage of the word line.

10. The method of claim 8, further comprising:
applying a first voltage to a plate line coupled with the ferroelectric material; and
applying a second voltage to the digit line concurrent with applying the first voltage to the plate line, wherein the voltage difference is applied across the ferroelectric material based at least in part on applying the first voltage and the second voltage.

11. The method of claim 8, wherein:
a first terminal of the first p-type transistor is coupled with a plate line of the memory cell, and
a second terminal of the first p-type transistor is coupled with the second p-type transistor.

12. The method of claim 8, wherein:
a first terminal of the second p-type transistor is coupled with the first p-type transistor, and
a second terminal of the second p-type transistor is coupled with the digit line and the n-type transistor.

13. The method of claim 8, wherein:
a first terminal of the n-type transistor is coupled with the ferroelectric material, the node, and the gate terminal of the first p-type transistor, and
a second terminal of the n-type transistor is coupled with the digit line and the second p-type transistor.

14. A method of reading a memory cell, comprising:
deactivating an n-type transistor coupled with a ferroelectric material and a digit line;
activating a first p-type transistor comprising a gate terminal coupled with a word line;
applying a voltage to a plate line coupled with the ferroelectric material and with a second p-type transistor that comprises a gate terminal coupled with a node between the n-type transistor and the ferroelectric material, wherein a voltage that is based at least in part on a capacitance of the ferroelectric material develops on the node based at least in part on applying the voltage to the plate line; and
sensing a signal on the digit line based at least in part on applying the voltage to the plate line, wherein a magnitude of the signal is based at least in part on the voltage on the node.

15. The method of claim 14, wherein:
an activation level of the second p-type transistor is based at least in part on the voltage on the node, and
the signal on the digit line is based at least in part on the activation level of the second p-type transistor.

16. The method of claim 14, wherein the signal comprises a current that flows through the first p-type transistor and the second p-type transistor.

17. The method of claim 14, wherein the n-type transistor is deactivated concurrently with activating the first p-type transistor.

18. The method of claim 14, wherein:
a gate terminal of the n-type transistor is coupled with the word line, and
the n-type transistor is activatable based at least in part on a voltage of the word line.

19. The method of claim 14, wherein:
a first terminal of the n-type transistor is coupled with the ferroelectric material, the node, and the gate terminal of the second p-type transistor, and
a second terminal of the n-type transistor is coupled with the digit line and the first p-type transistor.

20. The method of claim 14, wherein:
a first terminal of the first p-type transistor is coupled with the second p-type transistor, and
a second terminal of the first p-type transistor is coupled with the digit line and the n-type transistor.

21. The method of claim 14, wherein:
a first terminal of the second p-type transistor is coupled with the plate line, and
a second terminal of the second p-type transistor is coupled with the first p-type transistor.
